(19) United States
(12) Patent Application Publication
(10) Pub. No.: US 2025/0024723 A1
(43) Pub. Date: Jan. 16, 2025

(54) SEMICONDUCTOR DEVICE, DISPLAY DEVICE, PHOTOELECTRIC CONVERSION DEVICE, AND ELECTRONIC DEVICE

(71) Applicant: CANON KABUSHIKI KAISHA, Tokyo (JP)

(72) Inventor: Kazuya Notsu, Kanagawa (JP)

(21) Appl. No.: 18/765,435

(22) Filed: Jul. 8, 2024

(30) Foreign Application Priority Data
Jul. 13, 2023 (JP) 2023-115249
Mar. 25, 2024 (JP) 2024-047666

(51) Int. Cl. H10K 59/131

(52) U.S. Cl. CPC H10K 59/131

(57) ABSTRACT

A semiconductor device includes a semiconductor chip in which a plurality of terminal groups including a plurality of terminals disposed along a first direction are disposed along a second direction, wherein at least one of the plurality of terminal groups includes a first terminal, a second terminal adjacent to the first terminal in the first direction, a third terminal adjacent to the second terminal in the first direction, and a fourth terminal adjacent to the third terminal in the first direction, a spacing between the first terminal and the second terminal in the first direction is wider than a spacing between the second terminal and the third terminal in the first direction, and the spacing between the second terminal and the third terminal in the first direction is wider than a spacing between the third terminal and the fourth terminal in the first direction.

### BACKGROUND OF THE INVENTION

### Field of the Invention

The present invention relates to a semiconductor device, a display device, a photoelectric conversion device, and an electronic device.

### Description of the Related Art

Electronic device articles are required to become ever smaller, lighter and deliver higher performance, and thus the number of external output terminals of such devices is increasing rapidly. Accommodating this increase in the number of external output terminals may translate into a larger electronic device size, because conventional wire bonding connections are limited in terms of narrowing the pitch of the connection terminals. Therefore, techniques for flip-chip mounting of semiconductor chips to each other are drawing attention. In flip-chip mounting, pads having a reduced size can be connected to each other, in a semiconductor process, via connecting portions such as bumps; as a result the pitch of external output terminals can be made narrower than in conventional wire bonding connection. Joining methods for flip-chip mounting include ultrasonic joining and solder joining. To produce display devices such as organic ELs, a joining method is ordinarily resorted to a method that utilizes an ACF (anisotropic conductive film) that allows joining at a lower temperatures, for the purpose of suppressing element degradation derived from of heat in a joining process.

In a display device, for instance semiconductor chip terminals are mounted, by flip-chip mounting, on electrodes of a semiconductor substrate; however, electrical connection failures (disconnection or higher electrical resistance) may occur between the electrodes of the semiconductor substrate and the terminals of the semiconductor chip.

An ACF film is a film in which conductive particles are dispersed in a thermosetting resin. In a joining method utilizing an ACF as a joining member, heat and pressure are applied to a member having an ACF disposed thereon, between the electrodes and the terminals, to thereby elicit thermal curing of the thermosetting resin at the same time when the conductive particles are sandwiched between the electrodes and the terminals. Electrical connection between the electrodes and the terminals is accomplished as a result. In further detail, the thermosetting resin squashed by heat and pressure is pushed out of the semiconductor chip; in consequence, the thermosetting resin is thinned down and the conductive particles become nipped between the electrodes and the terminals. Electrical connection between the electrodes and the terminals is accomplished as a result.

In a case of a terminal array (or electrode array corresponding to the terminal array) having multiple rows of terminal groups arrayed with a short spacing between terminals, flowability of a thermosetting resin in the column direction is poor due to the narrow spacing between terminals. As a result, the thermosetting resin tends to pool at the central portion of the semiconductor chip, and thus it becomes difficult to reduce the thickness of the thermosetting resin, even upon application of heat and pressure, and defects in electrical connection between electrodes and terminals are likely to occur. The thermosetting resin has to be pushed out in the row direction because of this poor flowability of the thermosetting resin in the column direction; in a case however of a semiconductor chip that is elongated in the row direction, it is difficult to push the thermosetting resin out in the row direction, defects in electrical connection between electrodes and terminals are particularly likely to occur.

In ultrasonic joining, there may be used adhesives such as epoxy resins or acrylic resins, and thermally curable films such as NCFs (non-conductive adhesive films), for the purpose of enhancing joining strength and reliability. Similarly to the above joining using ACFs, in this case as well resin flowability at the central portion of the semiconductor chip is poor, and defects in electrical connection between electrodes and terminals are likely to occur.

In the art disclosed in Japanese Patent Application Publication No. 2016-127259, dummy bumps are disposed between two respective bump groups. In the art disclosed in Japanese Patent Application Publication No. 2004-356566, multiple bumps are disposed so as to surround the central portion of a semiconductor chip.

In the configuration disclosed in Japanese Patent Application Publication No. 2016-127259, resin flowability cannot be improved, and defects in electrical connection between electrodes and terminals are likely to occur. In the configuration disclosed Japanese Patent Application Publication No. 2004-356566, there is nowhere for the resin to escape, and as a result resin flowability is very poor, and defects in electrical connection between electrodes and terminals are extremely prone to occur.

### SUMMARY OF THE INVENTION

The present invention has been made in the light of the above problems, provides a semiconductor device in which terminals of a semiconductor chip are satisfactorily flip-chip mounted onto the electrodes of a semiconductor substrate.

A semiconductor device according to the present invention includes a semiconductor chip in which a plurality of terminal groups including a plurality of terminals disposed along a first direction are disposed along a second direction that intersects the first direction, wherein at least one of the plurality of terminal groups includes a first terminal, a second terminal adjacent to the first terminal in the first direction, a third terminal adjacent to the second terminal on an opposite side thereof from the first terminal in the first direction, and a fourth terminal adjacent to the third terminal on an opposite side thereof from the second terminal in the first direction, a spacing between the first terminal and the second terminal in the first direction is wider than a spacing between the second terminal and the third terminal in the first direction, and the spacing between the second terminal and the third terminal in the first direction is wider than a spacing between the third terminal and the fourth terminal in the first direction.

Further features of the present invention will become apparent from the following description of exemplary embodiments with reference to the attached drawings.

### BRIEF DESCRIPTION OF THE DRAWINGS

FIG. 1A is a schematic diagram of a semiconductor device according to Embodiments 1 to 7;

FIG. 1B is a cross-sectional diagram of a semiconductor device according to Embodiments 1 to 7;

FIG. 2 is a plan-view diagram of a conventional semiconductor chip;

FIG. 3A to 3F are explanatory diagrams of a method for producing a semiconductor device according to Embodiments 1 to 7;

FIG. 4A, FIG. 4C and FIG. 4D are plan-view diagrams of a semiconductor chip according to Embodiment 1;

FIG. 4B is a cross-sectional diagram of a semiconductor chip according to Embodiment 1;

FIG. 5A, FIG. 5C and FIG. 5D are plan-view diagrams of a semiconductor chip according to Embodiment 2;

FIG. 5B is a cross-sectional diagram of a semiconductor chip according to Embodiment 2;

FIG. 6A to 6C are plan-view diagrams of a semiconductor chip according to Embodiment 3;

FIG. 7A to 7C are plan-view diagrams of a semiconductor chip according to Embodiment 4;

FIG. 8A to 8C are plan-view diagrams of a semiconductor chip according to Embodiment 5;

FIG. 9A to 9C are plan-view diagrams of a semiconductor chip according to Embodiment 6;

FIG. 10A to 10C are plan-view diagrams of a semiconductor chip according to Embodiment 7;

FIG. 11 is a schematic diagram illustrating a display device according to Embodiment 8;

FIG. 12A is a schematic diagram illustrating an imaging device according to Embodiment 8;

FIG. 12B is a schematic diagram illustrating an electronic device according to Embodiment 8;

FIG. 13A and FIG. 13B are schematic diagrams illustrating a display device according to Embodiment 8;

FIG. 14A is a schematic diagram illustrating a lighting device according to Embodiment 8;

FIG. 14B is a schematic diagram illustrating a moving body according to Embodiment 8; and

FIG. 15A and FIG. 15B are schematic diagrams illustrating a wearable device according to Embodiment 8.

### DESCRIPTION OF THE EMBODIMENTS

Embodiments for carrying out the present invention will be explained below with reference to accompanying drawings. In the explanation and drawings that follow, configurations shared across the drawings are denoted by shared reference symbols. Therefore, shared configurations will be explained while interchangeably referring to multiple drawings; also, explanations bearing on configurations denoted by shared reference symbols may be omitted as appropriate.

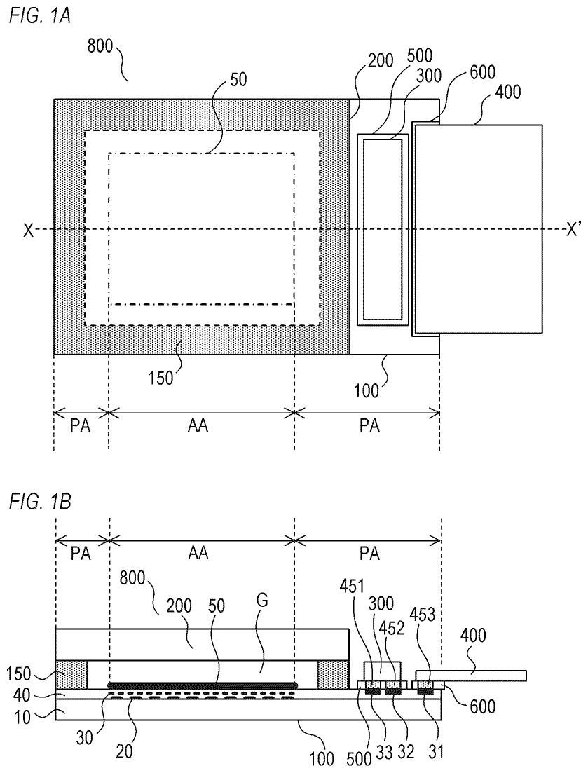

FIG. 1A is a plan-view diagram of a semiconductor device 800 as viewed from above. An arrangement in a plan view denotes herein an arrangement with the semiconductor device 800 viewed from a direction perpendicular to a main surface of a semiconductor substrate 100 (normal direction relative to the main surface). A given member that is overlapped by another member can herein be seen through in a plan view. A counter substrate 200 overlaps the semiconductor substrate 100 in a plan view of the main surface of the semiconductor substrate 100. The direction in which the counter substrate 200 faces the semiconductor substrate 100 (facing direction) is a direction perpendicular to the main surface of the semiconductor substrate 100 (normal direction relative to the main surface). The semiconductor substrate 100 has an effective element area AA in which effective elements are provided on a first main surface of a substrate 10, and a peripheral area PA positioned around the effective element area AA. The effective element area AA is rectangular, having a diagonal length of for instance 5 mm to 50 mm. The peripheral area PA may include a peripheral circuit area (not shown) having a peripheral circuit disposed therein. In the case for instance of a display device, the peripheral circuit includes for instance a drive circuit for driving effective pixels and a processing circuit (for instance a DAC (digital-to-analog conversion circuit)) for processing signals that are inputted to the effective pixels. The peripheral area PA is positioned outward of the effective element area AA, and can include a non-effective element area (not shown) in which non-effective elements are provided. A non-effective element is herein an element that does not function as an effective element, and may be for instance a dummy element, a reference element, a test element or a monitor element. A resin layer 150 that connects the counter substrate 200 and the semiconductor substrate 100 is provided in the peripheral area PA. The term connection may also be construed also as bonding or joining. A wiring board 400 and a semiconductor chip 300 are electrically connected to the semiconductor substrate 100, in the peripheral area PA.

FIG. 1B is an X-X′ cross-sectional diagram of the semiconductor device 800 of FIG. 1A. The semiconductor device 800 includes the semiconductor substrate 100, the counter substrate 200, the resin layer 150, the wiring board 400 and the semiconductor chip 300. The counter substrate 200 is disposed facing the semiconductor substrate 100 across a gap G in between. The resin layer 150 connects the counter substrate 200 and the semiconductor substrate 100. The wiring board 400 is electrically connected to the semiconductor substrate 100 via an electrode section 31 and a connection member 600. The semiconductor chip 300 is electrically connected to the semiconductor substrate 100 via electrode sections 32, 33 and a connection member 500. A semiconductor element 20, a wiring layer 30, an interlayer insulating layer 40 and a functional element 50 are provided in the effective element area AA of the semiconductor substrate 100. A peripheral circuit (not shown) is provided in the peripheral area PA of the semiconductor substrate 100. A conductive member such as an ACF (anisotropic conductive adhesive film), an NCF (non-conductive adhesive film), an epoxy resin, an acrylic resin or the like is used in the connection members 500, 600. The counter substrate 200 is disposed facing the semiconductor substrate 100, so as to cover all of the effective element area AA and part of the peripheral area PA. The resin layer 150, which is provided in the peripheral area PA of the semiconductor substrate 100, connects the semiconductor substrate 100 and the counter substrate 200.

The gap G is provided between the semiconductor substrate 100 and the counter substrate 200. The gap G may be filled with a resin in a case where it is necessary to suppress intrusion of moisture into the functional element 50. The filling resin may be identical to the resin of the resin layer 150, or may be different. Any transparent resin, for instance an acrylic resin or epoxy resin, can be used as the filling resin.

The substrate 10 is made up of a semiconductor such as single crystal silicon. The semiconductor element 20 is a transistor or a diode, such that at least part thereof is provided within the substrate 10. The wiring layer 30 includes a multilayer wiring, for instance of aluminum layers or copper layers, and plugs such as via plugs or contact plugs. The electrode sections 31, 32, 33 may be formed in the same layer as that of the wiring layer 30.

The interlayer insulating layer 40 includes a plurality of interlayer insulating layers, and is for instance made up of a silicon oxide layer, a silicon nitride layer are a silicon carbide layer. Silicon oxynitride and silicon carbonitride contain nitrogen and silicon as main elements, and accordingly can be regarded as kinds of silicon nitride. The functional element 50 is provided in the effective element area AA of the semiconductor substrate 100. The functional element 50 is a display element or a photoelectric conversion element; in the case of a display element, the functional element 50 is an EL element in an ELD (electroluminescent display), a liquid crystal element in an LCD (liquid crystal display), or a reflective element in a DMD (digital mirror device).

The functional element 50 is connected to the wiring layer 30 by way of vias (not shown) provided in the interlayer insulating layer 40, and is electrically connected to the semiconductor element 20 via the wiring layer 30. For instance a passivation film for suppressing intrusion of moisture, oxygen or the like, a color filter layer and a lens structure, can be provided on the functional element 50.

The semiconductor substrate 100 is configured thus as described above, such that the resin layer 150 is provided in the peripheral area PA of the semiconductor substrate 100, and the counter substrate 200 is affixed to the semiconductor substrate 100 via the resin layer 150. Any light-transmitting material such as glass or acrylic can be used in the counter substrate 200; alkali-free glass is suitably used herein. The thickness of the counter substrate 200 is for instance 0.7 mm. Preferably, an anti-reflection film (AR film for short) is formed on either main surface, or on both main surfaces, of the counter substrate 200. Formation of an AR film results in enhanced efficiency of incident light on the functional element 50 in a case where the functional element 50 is a photoelectric conversion element, and results in enhanced efficiency of light extraction from the functional element 50 in a case where the functional element 50 is a display element.

The semiconductor chip 300 is connected, via the connection member 500, to the electrode sections 32, 33 disposed in the peripheral area PA of the semiconductor substrate 100, and the wiring board 400 is connected to the electrode section 31 via the connection member 600.

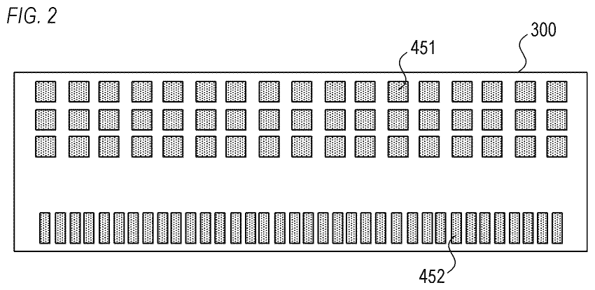

The semiconductor chip 300 is a semiconductor chip provided with a drive circuit, and terminals 451, 452 such as Au bumps or Cu bumps are provided at the surface at which the semiconductor chip 300 is connected to the semiconductor substrate 100. FIG. 2 is a plan-view diagram of the semiconductor chip 300 as viewed from above. FIG. 2 illustrates a conventional configuration (basic configuration); an explanation follows next on a configuration according to an embodiment of the present invention. Terminals 451 are output terminals, while terminals 452 are input terminals. There are ordinarily numerous output terminals; herein a desired number of output terminals is arranged by reducing the size of the output terminals or by increasing the number of rows of output terminals (number of output terminal groups, each including a plurality of output terminals, disposed along the row direction). In an arrangement of about 2,000 to 10,000 output terminals, ordinarily the length of one side of each output terminal is from about 10 μm to 100 μm, while the height of the output terminal is from about 3 μm to 50 μm. The spacing between the output terminals is from about 10 μm to 100 μm, and the number of rows of output terminals (number of output terminal groups) is from about 3 to 20 rows. The electrode section 33 includes a plurality of electrodes to which the output terminals 451 are respectively connected via the connection member 500. The number of input terminals is ordinarily smaller than the number of output terminals and thus the input terminals are required to have low electrical resistance; therefore, the size of the input terminals is preferably large. In an arrangement of about 300 to 2,000 input terminals, ordinarily the length of one side of the input terminals is from about 10 μm to 200 μm, and the height of the input terminals is from about 3 μm to 50 μm. The spacing between the input terminals is from about 10 μm to 50 μm, and the number of input terminal rows (number of input terminal groups including a plurality of input terminals at dissimilar positions in the row direction) is from about 1 to 5 rows. The electrode section 32 includes a plurality of electrodes to which a multiple input terminals 452 are respectively connected via the connection member 500.

The wiring board 400 is a flexible circuit board such as a glass epoxy board or a polyimide film having a wiring pattern provided thereon, for instance with terminals 453 in the form of Au bumps or Cu bumps provided on the surface of the wiring board 400 connected to the semiconductor substrate 100.

The connection member 500 of the semiconductor substrate 100 and the semiconductor chip 300 and the connection member 600 of the semiconductor substrate 100 and the wiring board 400 are each made up of an ACF, an NCF, an epoxy resin an acrylic resin or the like. For instance, the electrodes of the semiconductor substrate 100 and the terminals of the semiconductor chip 300 are electrically connected to each other, and the electrodes of the semiconductor substrate 100 and the terminals of the wiring board 400 are electrically connected to each other, by thermocompression bonding or ultrasonic compression joining. An ACF is herein a film in which conductive particles are dispersed in a thermosetting resin, and can be thus be construed as an anisotropic conductive resin. An epoxy resin or acrylic resin is used as the thermosetting resin. The size and number of conductive particles are selected depending on the size of the terminals; in a general ACF, for instance, the size (diameter) of the conductive particles is from about 1 μm to 50 μm, and the number of conductive particles (area density) is for instance from about 10,000 to 100,000 particles/mm². Connection strength and reliability between electrodes and terminals can be improved by using an NCF, an epoxy resin or an acrylic resin.

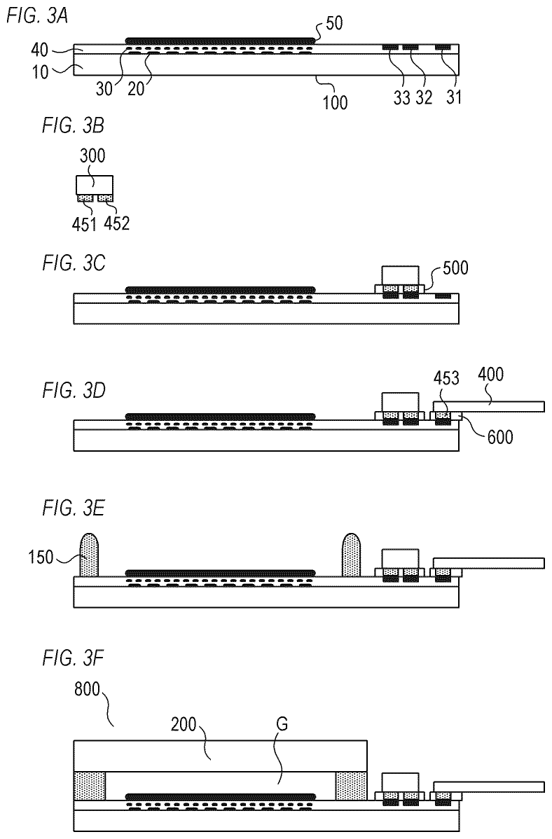

A method for producing an organic EL display device, which is an example of the semiconductor device 800, will be explained next with reference to FIG. 3A to 3F.

FIG. 3A is a cross-sectional diagram at a point in time at which the production process of the semiconductor substrate 100 is complete. The semiconductor substrate 100 has the substrate 10. For instance silicon can be used in the substrate 10. The semiconductor element 20, for instance a transistor, is formed on the main surface of the substrate 10. The interlayer insulating layer 40 is formed on the main surface of the substrate 10 on which the semiconductor element 20 is formed. Silicon oxide, silicon nitride, silicon carbide or the like is used in the interlayer insulating layer 40. Contact plugs (not shown) electrically connected to the semiconductor element 20 are disposed in the interlayer insulating layer 40. The contact plugs are filled by a conductive member such as tungsten. The wiring layer 30 that is electrically connected to the semiconductor element 20 via contact plugs is provided in the interior of the interlayer insulating layer 40. A metallic material such as aluminum or copper is used in the wiring layer 30. A barrier metal such as Ti, Ta, TiN or TaN may be provided at the interface between the interlayer insulating layer 40 and the wiring layer 30, for the purpose of suppressing metal diffusion into the interlayer insulating layer 40. The electrode sections 31, 32, 33 are formed in the same layer as any of the wiring layers 30, in the peripheral area PA of the substrate 10. Openings (not shown) from which the interlayer insulating layer 40 has been removed are provided above the electrode sections 31, 32, 33, such that the electrode sections 31, 32, 33 are exposed by the openings.

An organic EL element is provided as a functional element 50 on the interlayer insulating layer 40, in the effective element area AA. The functional element 50 is electrically connected to the wiring layer 30 by way of through-holes (not shown). The functional element 50 includes pixel electrodes, counter electrodes, and an organic light emitting layer (all not shown) provided between pixel electrodes and the counter electrodes. A hole injection layer and a hole transport layer may be formed between the organic light-emitting layer and the pixel electrodes, for the purpose of facilitating injection and transport of holes from the pixel electrodes. An electron transport layer and an electron injection layer may be formed between the organic light-emitting layer and the counter electrodes, for the purpose of facilitating injection and transport of electrons from the counter electrodes. A sealing passivation film (not shown) for suppressing moisture permeation may be formed on the functional element 50. A color filter layer and a lens structure for increasing light extraction efficiency may be provided on the passivation film.

FIG. 3B is a cross-sectional diagram of the semiconductor chip 300. Electrical wiring is formed, and opening pads for electrical connection are formed, on the semiconductor substrate, for instance by semiconductor processing, and the terminals 451, 452 of Au or Cu are formed for instance by electroplating, on the opening pads.

As illustrated in FIG. 3C, the connection member 500 is affixed on the electrode sections 32, 33 of the semiconductor substrate 100, such that the terminals 451, 452 (plurality of terminals) of the semiconductor chip 300 are thermocompression-bonded to the electrode sections 32, 33 (plurality of electrodes) of the semiconductor substrate 100 by way of the connection member 500. The terminals 451, 452 (plurality of terminals) of the semiconductor chip 300 become electrically connected as a result to the electrode sections 32, 33 (plurality of electrodes) of the semiconductor substrate 100. The thermocompression bonding temperature is preferably a temperature, for instance 100° C., at which the functional element 50 does not thermally degrade. For instance the connection member is an ACF, and contains conductive particles in an epoxy resin binder. The terminals 451, 452 (plurality of terminals) of the semiconductor chip 300 are electrically connected, by the conductive particles, to the electrode sections 32, 33 (plurality of electrodes) of the semiconductor substrate 100. The connection method involved is not particularly limited, and may be ultrasonic compression joining. Herein an NCF, an epoxy resin or an acrylic resin may be used as the connection member 500; this allows improving connection strength and reliability between electrodes and terminals.

As illustrated in FIG. 3D, the terminals 453 (plurality of terminals) of the wiring board 400 are thermocompression-bonded or ultrasonic compression-bonded to the electrode section 31 (plurality of electrodes) of the semiconductor substrate 100 via the connection member 600. The terminals 453 (plurality of terminals) of the wiring board 400 become electrically connected as a result to the electrode section 31 (plurality of electrodes) of the semiconductor substrate 100. The wiring board 400 is for instance a flexible circuit board in which a copper wiring pattern is formed on a polyimide base material. The connection member 600 (underfill resin) may be omitted; however, reliability and connection strength between electrodes and terminals can be improved by providing the connection member 600.

As illustrated in FIG. 3E, the resin layer 150 is formed, by coating, on the peripheral area PA of the semiconductor substrate 100. The resin layer 150 is applied so as to surround the effective element area AA. The resin layer 150 needs to be formed to a thickness such that the semiconductor substrate 100 and the counter substrate 200 are prevented from coming into contact with each other; the resin layer 150 is preferably formed out of a resin having a viscosity of 10,000 mPa·s or higher. A resin obtained by kneading of spacers in the form of glass beads or resin beads of predetermined size may be used in the resin layer 150. The thickness of the resin layer 150 can be easily controlled that way. Any resin material such as an epoxy resin or acrylic resin is used herein in the resin layer 150. For instance the resin layer 150 is formed by applying an epoxy resin mixed with 10 μm to 100 μm resin beads, preferably 30 μm resin beads, in accordance with a dispensing method.

As illustrated in FIG. 3F, the counter substrate 200 is provided on the resin layer 150, so as to face the main surface of the semiconductor substrate 100, whereupon the resin layer 150 is cured. When the counter substrate 200 is provided on the resin layer 150, the resin layer 150 spreads horizontally (left-right direction in the figure) on account of the load of the counter substrate 200. Therefore, the load of the counter substrate 200 is controlled so that the resin layer 150 does not wet and spread over the effective element area AA of the semiconductor substrate 100. The resin layer 150 is cured for instance by ultraviolet rays. Any transparent substrate, for instance glass or acrylic, can be used as the counter substrate 200; for instance alkali-free glass can be used herein. The thickness of the resin layer 150 after curing is for instance from 10 μm to 100 μm. The organic EL display device is completed as a result of the above steps.

### Embodiment 1

Embodiment 1 will be explained next. In Embodiment 1, the terminal groups of the semiconductor chip 300 include one or more specific terminal groups. In a specific terminal group, one terminal is defined herein as the first terminal, a terminal adjacent to the first terminal from the right is defined as a second terminal, and a terminal adjacent to the second terminal from the right is defined as a third terminal. The spacing between the first terminal and the second terminal in the row direction is set to be wider than the spacing between the second terminal and the third terminal in the row direction. Specifically, the spacing between terminals at a central portion of a specific terminal group in the row direction is set to be wider than the spacing between terminals at the end portion of the specific terminal group in the row direction. As a result there is improved the flowability of the resin flowing from the central portion of the semiconductor chip 300 in a column direction (direction perpendicular to the row direction). In consequence the thickness of the resin can be easily made uniform within the plane of the semiconductor chip 300 having the plurality of terminals, and likewise the terminals of the semiconductor chip 300 can be satisfactorily connected to the electrodes of the semiconductor substrate 100. Preferably, the spacing between terminals at the central portion of a specific terminal group is for instance from 50 μm to 200 μm.

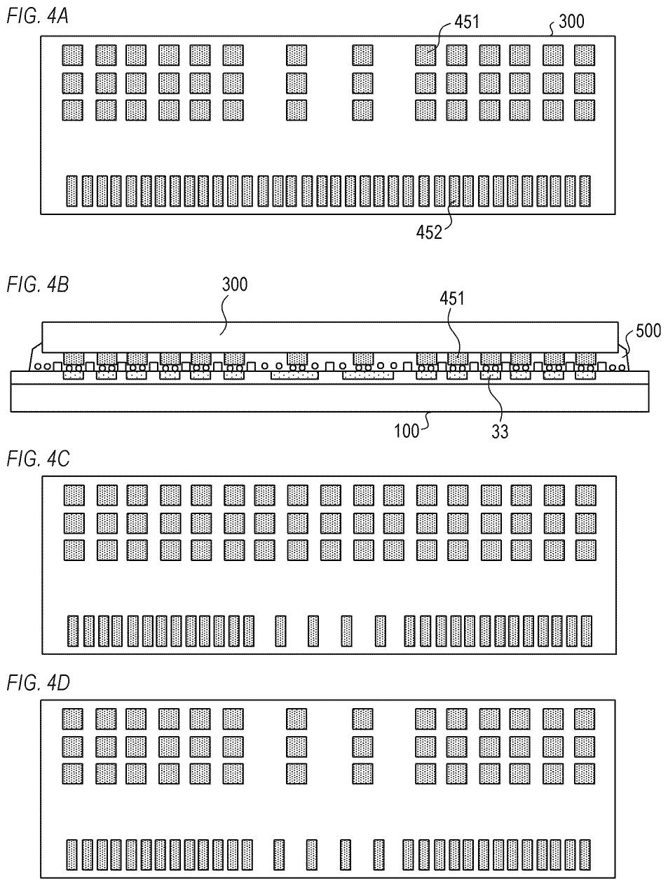

FIG. 4A, FIG. 4C and FIG. 4D are plan-view diagrams of the semiconductor chip 300 according to Embodiment 1 as viewed from above. FIG. 4B is a cross-sectional diagram of the semiconductor device 800 in which the semiconductor substrate 100 and the semiconductor chip 300 of FIG. 4A are connected to each other, as viewed from the side of the output terminals 451.

In FIG. 4A, the spacing between the output terminals 451 at the central portion of an output terminal group in the row direction (left-right direction in the figure) is wider than the spacing between the output terminals 451 at the end portion of the output terminal group in the row direction. The spacing between the output terminals 451 at the central portion of the output terminal group is an equal spacing, and the spacing between the output terminals 451 at the end portion of the output terminal group is likewise an equal spacing. In FIG. 4C, the spacing between the input terminals 452 at the central portion of an input terminal group in the row direction is wider than the spacing between the input terminals 452 at the end portion of the input terminal group in the row direction. The spacing between the input terminals 452 at the central portion of the input terminal group is an equal spacing, and also the spacing between the input terminals 452 at the end portion of the input terminal group is an equal spacing.

In FIG. 4D, the spacing between the output terminals 451 at the central portion of the output terminal group is wider than the spacing between the output terminals 451 at the end portion of the output terminal group. The spacing between the output terminals 451 at the central portion of the output terminal group is an equal spacing, and also the spacing between the output terminals 451 at the end portion of the output terminal group is an equal spacing. In FIG. 4D the spacing between the input terminals 452 at the central portion of the input terminal group is wider than the spacing between the input terminals 452 at the end portion of the input terminal group. The spacing between the input terminals 452 at the central portion of the input terminal group is an equal spacing, and also the spacing between the input terminals 452 at the end portion of the input terminal group is an equal spacing. A more pronounced flowability improvement effect than those of in FIG. 4A and FIG. 4C can be expected to be elicited by adapting thus both the spacing between the output terminals 451 of the output terminal group and the spacing between the input terminals 452 of the input terminal group. The spacing between the output terminals 451 at the central portion of the output terminal group may be equal to, or different from, the spacing between the input terminals 452 at the central portion of the input terminal group. The spacing between the output terminals 451 at the end portion of the output terminal group may be equal to, or different from, the spacing between the input terminals 452 at the end portion of the input terminal group.

### Embodiment 2

Embodiment 2 will be explained next. In a specific terminal group in Embodiment 2, one terminal is defined herein as the first terminal, a terminal adjacent to the first terminal from the right is defined as a second terminal, and a terminal adjacent to the second terminal from the right is defined as a third terminal. A terminal adjacent to the third terminal from the right is defined as a fourth terminal. The spacing between the first terminal and the second terminal in the row direction is wider than the spacing between the second terminal and the third terminal in the row direction, and the spacing between the second terminal and the third terminal in the row direction is wider than the spacing between the third terminal and the fourth terminal in the row direction. For instance the spacing between terminals of a specific terminal group (spacing between two mutually adjacent terminals, in the row direction) widens gradually with increasing proximity to the center of the specific terminal group in the row direction. As a result, the flowability of the resin flowing in the column direction, from the central portion of the semiconductor chip 300, is improved with respect to that of Embodiment 1. Preferably, the spacing between the terminals of a specific terminal group widens gradually, for instance in the range from 1 μm to 200 μm, with increasing proximity to the center of the specific terminal group. The spacing between terminals in the specific terminal group may be set to be become wider, or not, with increasing proximity to the center of the specific terminal group, in the entirety of the specific terminal group. The spacing between terminals in the specific terminal group may alternatively be set to be become wider with increasing proximity to the center of the specific terminal group, only for the central portion of the specific terminal group.

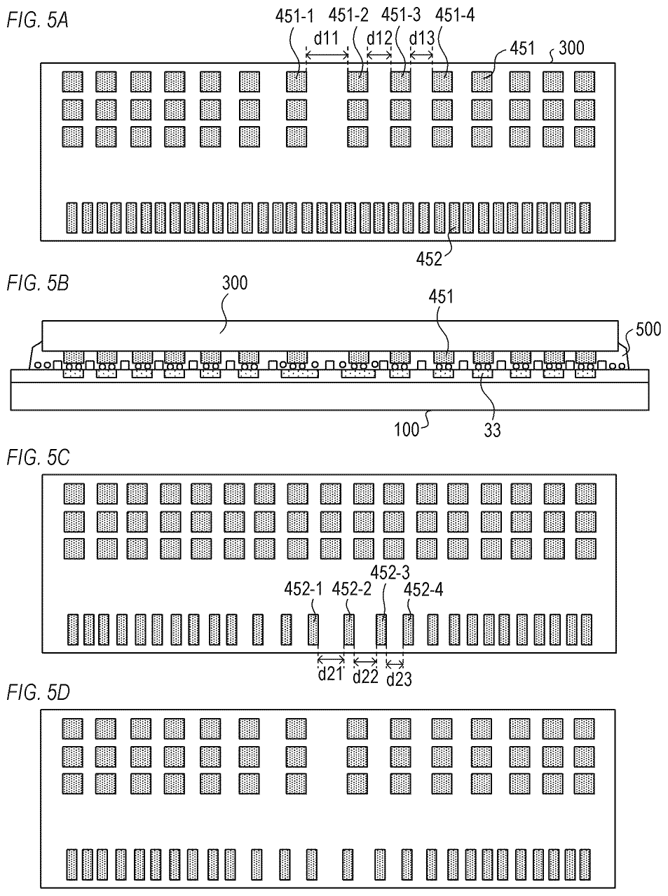

FIG. 5A, FIG. 5C and FIG. 5D are plan-view diagrams of the semiconductor chip 300 according to Embodiment 2, as viewed from above. FIG. 5B is a cross-sectional diagram of the semiconductor device 800 in which the semiconductor substrate 100 and the semiconductor chip 300 of FIG. 5A are connected to each other, as viewed from the side of the output terminals 451.

In FIG. 5A, the spacing between the output terminals 451 widens gradually with increasing proximity to the center of a respective output terminal group. Attention will be focused now on a first output terminal 451-1, a second output terminal 451-2, a third output terminal 451-3, and a fourth output terminal 451-4. The second output terminal 451-2 is adjacent to the first output terminal 451-1 from the right, the third output terminal 451-3 is adjacent to the second output terminal 451-2 from the right, and the fourth output terminal 451-4 is adjacent to the third output terminal 451-3 from the right. A spacing d11 between the first output terminal 451-1 and the second output terminal 451-2 is wider than a spacing d12 between the second output terminal 451-2 and the third output terminal 451-3, and the spacing d12 is wider than a spacing d13 between the third output terminal 451-3 and the fourth output terminal 451-4.

In FIG. 5C, the spacing between the input terminals 452 widens gradually with increasing proximity to the center of a respective input terminal group. Attention will be focused now on a first input terminal 452-1, a second input terminal 452-2, a third input terminal 452-3, and a fourth input terminal 452-4. The second input terminal 452-2 is adjacent to the first input terminal 452-1 from the right, the third input terminal 452-3 is adjacent to the second input terminal 452-2 from the right, and the fourth input terminal 452-4 is adjacent to the third input terminal 452-3 from the right. A spacing d21 between the first input terminal 452-1 and the second input terminal 452-2 is wider than a spacing d22 between the second input terminal 452-2 and the third input terminal 452-3, and the spacing d22 is wider than a spacing d23 between the third input terminal 452-3 and the fourth input terminal 452-4.

In FIG. 5D, the spacing between the output terminals 451 widens gradually with increasing proximity to the center of the output terminal group. In FIG. 5D, the spacing between the input terminals 452 widens gradually with increasing proximity to the center of the input terminal group. A more pronounced flowability improvement effect than those in FIG. 5A and FIG. 5C can be expected to be elicited by adapting thus both the spacing between the output terminals 451 of the output terminal group and the spacing between the input terminals 452 of the input terminal group.

### Embodiment 3

Embodiment 3 will be explained next. In Embodiment 3, the plurality of terminal groups of the semiconductor chip 300 include a first terminal group and a second terminal group. The spacing between the central portion of the first terminal group in the row direction and the central portion of the second terminal group in the row direction is set to be narrower than the spacing between an end portion of the first terminal group in the row direction and the end portion of the second terminal group in the row direction. The amount of resin confined between the central portion of the first terminal group and the central portion of the second terminal group can be reduced as a result. In consequence the thickness of the resin can be easily made uniform within the plane of the semiconductor chip 300 provided with the plurality of terminals, and likewise the terminals of the semiconductor chip 300 can be satisfactorily connected to the electrodes of the semiconductor substrate 100.

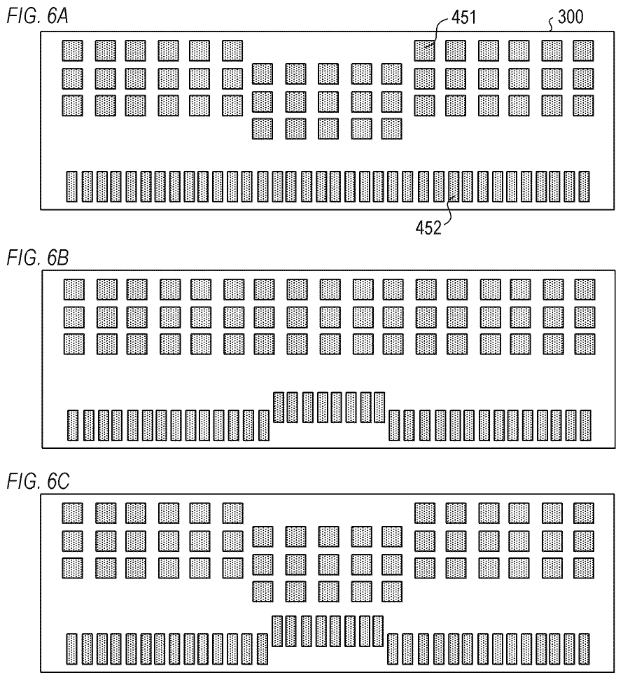

FIG. 6A, FIG. 6B and FIG. 6C are plan-view diagrams of the semiconductor chip 300 according to Embodiment 3, as viewed from above.

In FIG. 6A the positions of the output terminals 451 in the column direction differ between the end portion and the central portion of the output terminal group, so that the spacing between the central portion of the output terminal group and the central portion of the input terminal group is narrower than the spacings between the end portion of the output terminal group and the end portion of the input terminal group. In FIG. 6B the positions of the input terminals 452 in the column direction differ between the end portion and the central portion of the input terminal group, so that the spacing between the central portion of the output terminal group and the central portion of the input terminal group is narrower than the spacings between the end portion of the output terminal group and the end portion of the input terminal group.

In FIG. 6C the positions of the output terminals 451 in the column direction differ between the end portion and the central portion of the output terminal group, so that the spacing between the central portion of the output terminal group and the central portion of the input terminal group is narrower than the spacings between the end portion of the output terminal group and the end portion of the input terminal group. In FIG. 6C the positions of the input terminals 452 in the column direction differ between the end portion and the central portion of the input terminal group, so that the spacing between the central portion of the output terminal group and the central portion of the input terminal group is narrower than the spacings between the end portion of the output terminal group and the end portion of the input terminal group.

### Embodiment 4

Embodiment 4 will be explained next. In Embodiment 4 an intermediate portion is defined as a site between the end portion and the central portion of the first terminal group (or second terminal group) in the row direction. The spacing between the central portion of the first terminal group in the row direction and the central portion of the second terminal group in the row direction is set to be narrower than the spacing between the intermediate portion of the first terminal group in the row direction and the intermediate portion of the second terminal group in the row direction. The spacing between the intermediate portion of the first terminal group in the row direction and the intermediate portion of the second terminal group in the row direction is set to be narrower than the spacings between the end portion of the first terminal group in the row direction and the end portion of the second terminal group in the row direction. For instance the spacing between the first terminal group and the second terminal group is set to decrease gradually with increasing proximity to the center of the first terminal group (or second terminal group) in the row direction. The amount of resin confined between the central portion of the first terminal group and the central portion of the second terminal group can be reduced as a result.

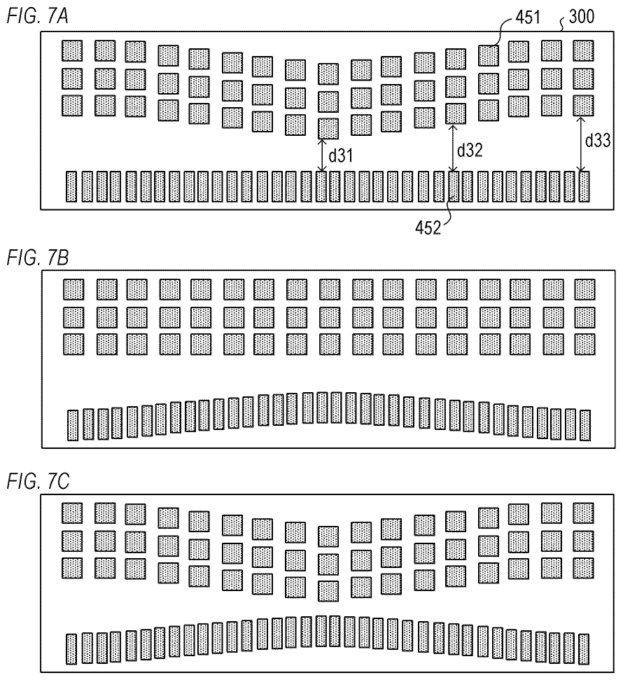

FIG. 7A, FIG. 7B and FIG. 7C are plan-view diagrams of the semiconductor chip 300 according to Embodiment 4, as viewed from above.

In FIG. 7A, the position of the output terminals 451 in the column direction varies in such a manner that the spacing between the output terminal group and the input terminal group narrows down gradually with increasing proximity to the center of the output terminal group (or input terminal group). In FIG. 7B, the position of the input terminals 452 in the column direction varies in such a manner that the spacing between the output terminal group and the input terminal group narrows down gradually with increasing proximity to the center of the output terminal group (or input terminal group).

In FIG. 7C, the position of the output terminals 451 in the column direction varies in such a manner that the spacing between the output terminal group and the input terminal group narrows down gradually with increasing proximity to the center of the output terminal group (or input terminal group). Also in FIG. 7C, the position of the input terminals 452 in the column direction varies in such a manner that the spacing between the output terminal group and the input terminal group narrows down gradually with increasing proximity to the center of the output terminal group (or input terminal group). In FIG. 7A to 7C a spacing d31 between the central portion of the output terminal group in the row direction and the central portion of the input terminal group in the row direction is narrower than a spacing d32 between the intermediate portion of the output terminal group in the row direction and the intermediate portion of the input terminal group in the row direction. The spacing d32 is narrower than a spacing d33 between the end portion of the output terminal group in the row direction and the end portion of the input terminal group in the row direction.

### Embodiment 5

Embodiment 5 will be explained next. Similarly to Embodiment 3, in Embodiment 5 as well the spacing between the central portion of the first terminal group in the row direction and the central portion of the second terminal group in the row direction is set to be narrower than the spacings between the end portion of the first terminal group in the row direction and the end portion of the second terminal group in the row direction.

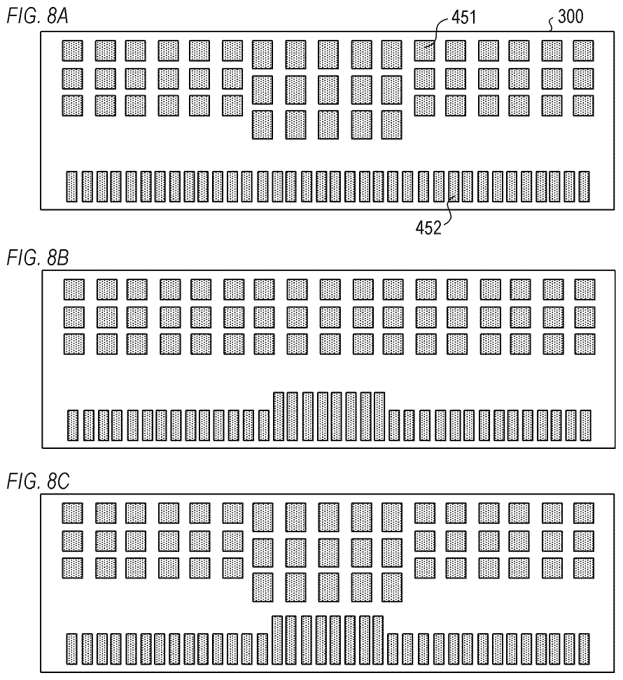

FIG. 8A, FIG. 8B and FIG. 8C are plan-view diagrams of the semiconductor chip 300 according to Embodiment 5, as viewed from above.

In FIG. 8A the size of the output terminals 451 in the column direction is set to be larger at the central portion of the output terminal group than at the end portion of the output terminal group, so that the spacing between the central portion of the output terminal group and the central portion of the input terminal group is narrower than the spacings between the end portion of the output terminal group and the end portion of the input terminal group. In FIG. 8B the size of the input terminals 452 in the column direction is to be larger at the central portion of the input terminal group than at the end portion of the input terminal group, so that the spacing between the central portion of the output terminal group and the central portion of the input terminal group is narrower than the spacings between the end portion of the output terminal group and the end portion of the input terminal group.

In FIG. 8C the size of the output terminals 451 in the column direction is to be larger at the central portion of the output terminal group than at the end portion of the output terminal group, so that the spacing between the central portion of the output terminal group and the central portion of the input terminal group is narrower than the spacings between the end portion of the output terminal group and the end portion of the input terminal group. Also in FIG. 8C the size of the input terminals 452 in the column direction is to be larger at the central portion of the input terminal group than at the end portion of the input terminal group, so that the spacing between the central portion of the output terminal group and the central portion of the input terminal group is narrower than the spacings between the end portion of the output terminal group and the end portion of the input terminal group.

### Embodiment 6

Embodiment 6 will be explained next. Similarly to Embodiment 4, in Embodiment 6 as well the spacing between the first terminal group and the second terminal group is set to decrease gradually with increasing proximity to the center of the first terminal group (or second terminal group) in the row direction.

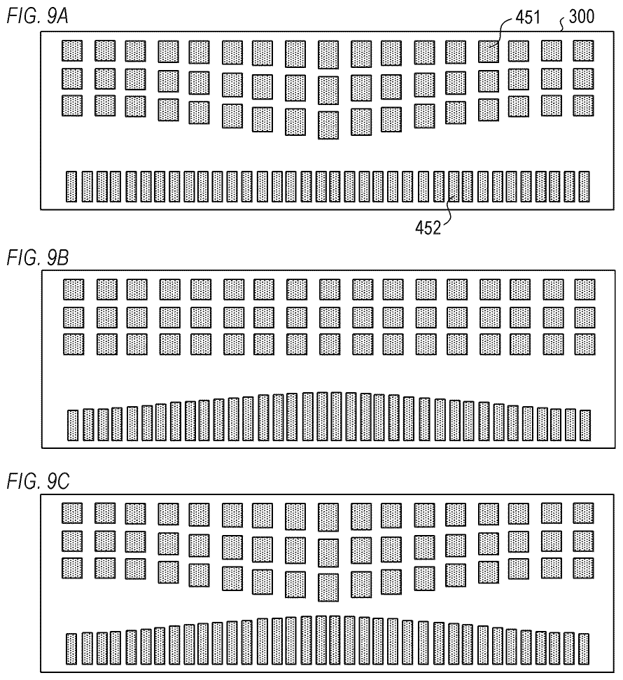

FIG. 9A, FIG. 9B and FIG. 9C are plan-view diagrams of the semiconductor chip 300 according to Embodiment 6, as viewed from above.

In FIG. 9A, the size of the output terminals 451 in the column direction varies in such a manner that the spacing between the output terminal group and the input terminal group narrows down gradually with increasing proximity to the center of the output terminal group (or input terminal group). In FIG. 9B, the size of the input terminals 452 in the column direction varies in such a manner that the spacing between the output terminal group and the input terminal group narrows down gradually with increasing proximity to the center of the output terminal group (or input terminal group).

In FIG. 9C, the size of the output terminals 451 in the column direction varies in such a manner that the spacing between the output terminal group and the input terminal group narrows down gradually with increasing proximity to the center of the output terminal group (or input terminal group). Also in FIG. 9C, the size of the input terminals 452 in the column direction varies in such a manner that the spacing between the output terminal group and the input terminal group narrows down gradually with increasing proximity to the center of the output terminal group (or input terminal group).

In Embodiments 3 to 6, one of the output terminal group and the input terminal group is defined as the first terminal group, and the other of the output terminal group input terminal group is defined as the second terminal group, with adaptations in the spacing between the output terminal group and the input terminal group, but the embodiments are not limited thereto. For instance the first terminal group and the second terminal group may both be an output terminal group, with adaptations in the spacing between the two output terminal groups.

### Embodiment 7

Embodiment 7 will be explained next. Embodiment 7 is a combination of Embodiment 1 and Embodiment 3. Also, Embodiment 7 may be a combination of Embodiment 1 and Embodiment 4, or a combination of Embodiment 1 and Embodiment 5, or a combination of Embodiment 1 and Embodiment 6. Further, Embodiment 7 may be a combination of Embodiment 2 and Embodiment 3, or a combination of Embodiment 2 and Embodiment 4, or a combination of Embodiment 2 and Embodiment 5, or a combination of Embodiment 2 and Embodiment 6.

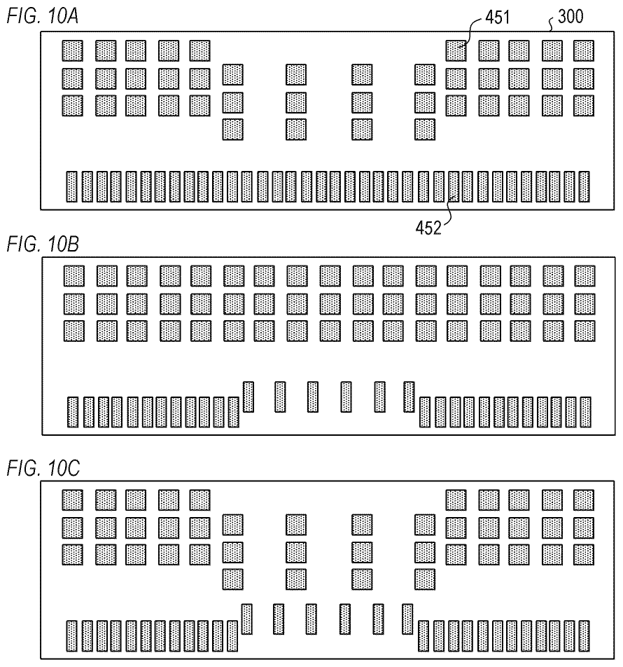

FIG. 10A, FIG. 10B and FIG. 10C are plan-view diagrams of the semiconductor chip 300 according to Embodiment 7, as viewed from above.

Similarly to FIG. 4A, in FIG. 10A the spacing between the output terminals 451 at the central portion of the output terminal group is wider than the spacing between the output terminals 451 at the end portion of the output terminal group. Similarly to FIG. 6A the positions of the output terminals 451 in the column direction differ between the end portion and the central portion of the output terminal group, so that the spacing between the central portion of the output terminal group and the central portion of the input terminal group is narrower than the spacings between the end portion of the output terminal group and the end portion of the input terminal group.

In FIG. 10B the spacing between the input terminals 452 at the central portion of the input terminal group is wider than the spacing between the input terminals 452 at the end portion of the input terminal group as in FIG. 4C. The positions of the input terminals 452 in the column direction differ between the end portion and the central portion of the input terminal group, so that the spacing between the central portion of the output terminal group and the central portion of the input terminal group is narrower than the spacings between the end portion of the output terminal group and the end portion of the input terminal group as in FIG. 6B.

In FIG. 10C both the spacing between the output terminals 451 of the output terminal group and the spacing between the input terminals 452 of the input terminal group are adapted as in FIG. 4D. Also in FIG. 10C, both the position of the output terminals 451 and the position of the input terminals 452 are adapted, as in FIG. 6C.

In Embodiments 1 to 7 examples have been explained in which multiple terminal groups, each including a plurality of terminals exhibiting dissimilar positions in the row direction, are disposed along the column direction, but the array directions are not limited to a row direction and/or a column direction. For instance a terminal group may include a plurality of terminals disposed along the column direction, and a plurality of terminal groups may be disposed along the row direction. Two other mutually intersecting directions that may be adopted herein; at least one of the row direction and column direction may be an oblique direction.

### Embodiment 8

In Embodiment 8 examples will be explained in which the semiconductor device 800 according to Embodiments 1 to 7 is applied to various devices. In a case where the semiconductor device 800 is used in a display device, the semiconductor substrate 100 is a display element substrate, with a light-emitting element being disposed in the effective element area AA. In a case where the semiconductor device 800 is used as an imaging device, the semiconductor substrate 100 is an imaging element substrate, with an imaging element being disposed in the effective element area AA.

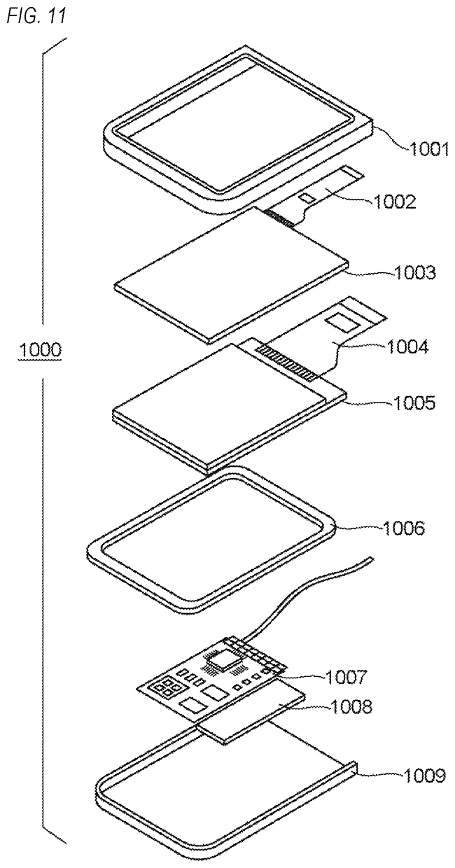

FIG. 11 is a schematic diagram illustrating a display device 1000, which is an example of a display device according to Embodiment 8. The display device 1000 may have a touch panel 1003, a display panel 1005, a frame 1006, a circuit board 1007 and a battery 1008, between an upper cover 1001 and a lower cover 1009.

The display panel 1005 is a display unit that includes the semiconductor device 800 according to Embodiments 1 to 7, and that performs display using light emitted from the semiconductor device 800. Flexible printed circuits FPCs 1002, 1004 are connected to the touch panel 1003 and the display panel 1005. A control circuit including transistors is printed on the circuit board 1007, and performs various control tasks such as controlling the display panel 1005. The battery 1008 may be omitted if the display device is not a portable device; even if the display device is a portable device, the battery 1008 may be provided at a different position. The display device 1000 may have three types of color filters respectively corresponding to red, green and blue. The color filters may be disposed in a delta arrangement.

The display device 1000 may be used as a display unit of a mobile terminal. In that case the display device 1000 may have both a display function and an operation function. Mobile terminals include mobile phones such as smartphones, tablets and head-mounted displays.

The display device 1000 may be used in a display unit of an imaging device that has an optical unit having a plurality of lenses, the display unit having also an imaging element which receives light having passed through the optical unit. The imaging device may have a display unit that displays information acquired by the imaging element (i.e. displaying for instance an image captured by an imaging element). The display unit may be a display unit exposed outside the imaging device, or may be a display unit disposed within a finder. The imaging device may be for instance a digital camera or a digital video camera.

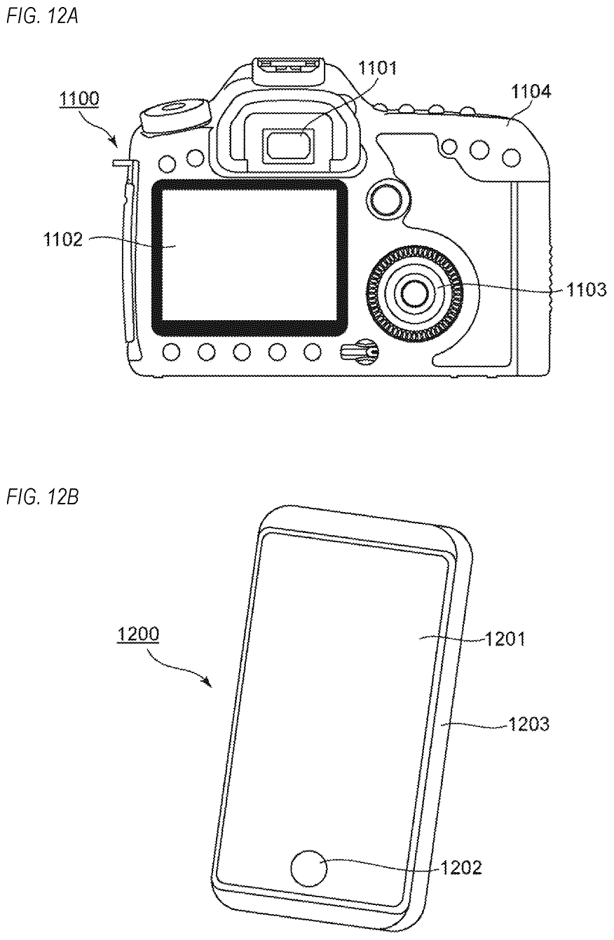

FIG. 12A is a schematic diagram illustrating an imaging device 1100, which is an example of the imaging device according to Embodiment 8. The imaging device 1100 may have a viewfinder 1101, a rear display 1102, an operation unit 1103 and a housing 1104. The viewfinder 1101 may have the display device according to Embodiment 8 (display device having the semiconductor device 800 according to Embodiments 1 to 7 and that performs display using light emitted from the semiconductor device 800). In that case, the display device may display not only an image to be captured, but also for instance environment information and imaging instructions. The environment information may include for instance external light intensity, external light orientation, the moving speed of an object, and the chance of the object being blocked by an obstacle. The rear display 1102 may also have the display device according to Embodiment 8.

The timing suitable for imaging is short, and hence information should be displayed as soon as possible. It is therefore preferable to use a display device that utilizes in turn an organic light-emitting element of fast response speed. A display device that has an organic light-emitting element can be more suitable, for devices required high display speed, than liquid crystal display devices.

The imaging device 1100 has an optical unit, not shown. The optical unit has a plurality of lenses, and forms an image of the light, on the imaging element accommodated in the housing 1104. The lenses can be adjusted through adjustment of the relative positions thereof. This operation can also be performed automatically. The imaging device 1100 may be referred to as a photoelectric conversion device. The photoelectric conversion device can encompass, as an imaging method other than sequential imaging, a method that involves detecting a difference relative to a previous image, and a method that involves cutting out part of a recorded image.

FIG. 12B is a schematic diagram illustrating an electronic device 1200, which is an example of an electronic device according to Embodiment 8. The electronic device 1200 has a display unit 1201, an operation unit 1202 and a housing 1203. The display unit 1201 has the semiconductor device 800 according to Embodiments 1 to 7, and performs display using light emitted from the semiconductor device 800. The electronic device 1200 may have, within the housing 1203, a circuit, a printed circuit board having the circuit, a battery, and a communication unit that communicates with the exterior. The operation unit 1202 may be a button, or a touch panel-type reaction unit. The operation unit may be a biometric recognition unit which for instance performs unlocking upon recognition of a fingerprint. The electronic device having a communication unit can also be referred to as a communication device. The electronic device may further have a camera function, by being provided with a lens and an imaging element. Images captured by way of the camera function are displayed on the display unit. Examples of the electronic device include smartphones and notebook computers.

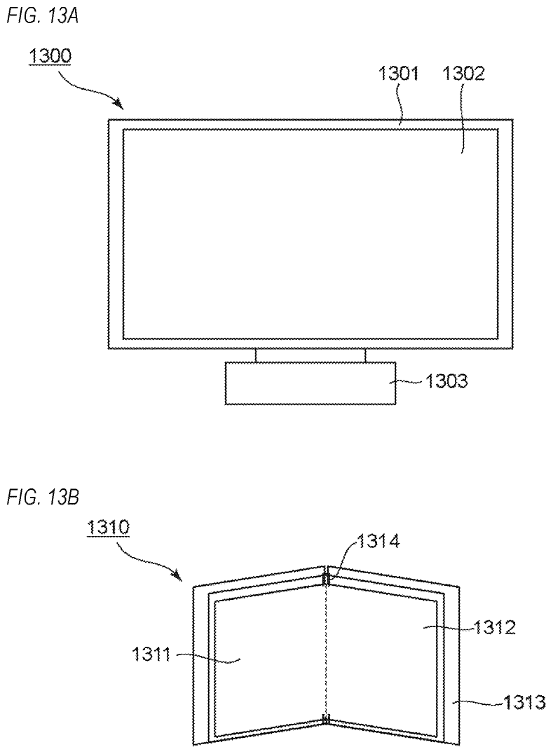

FIG. 13A is a schematic diagram illustrating a display device 1300, which is an example of a display device according to Embodiment 8. The display device 1300 is a display device such as a television monitor or a PC monitor. The display device 1300 has a frame 1301, a display unit 1302, and a base 1303 that supports the frame 1301 and the display unit 1302. The display unit 1302 has the semiconductor device 800 according to Embodiments 1 to 7, and performs display using light emitted from the semiconductor device 800. The form of the base 1303 is not limited to the form illustrated in FIG. 13A. The lower side of the frame 1301 may also double as the base 1303. The frame 1301 and the display unit 1302 may be curved. The radius of curvature of the foregoing may be at least 5000 mm and not more than 6000 mm.

FIG. 13B is a schematic diagram illustrating a display device 1310, which is an example of another display device according to Embodiment 8. The display device 1310 is a so-called foldable display device, configured to be foldable. The display device 1310 has a first display unit 1311, a second display unit 1312, a housing 1313 and a folding point 1314. The first display unit 1311 and the second display unit 1312 each has the semiconductor device 800 according to Embodiments 1 to 7, and performs display using light emitted from the semiconductor device 800. The first display unit 1311 and the second display unit 1312 may be one seamless display device. The first display unit 1311 and the second display unit 1312 can be separated at the folding point. The first display unit 1311 and the second display unit 1312 may display different images; alternatively, the first display unit 1311 and the second display unit 1312 may display one image.

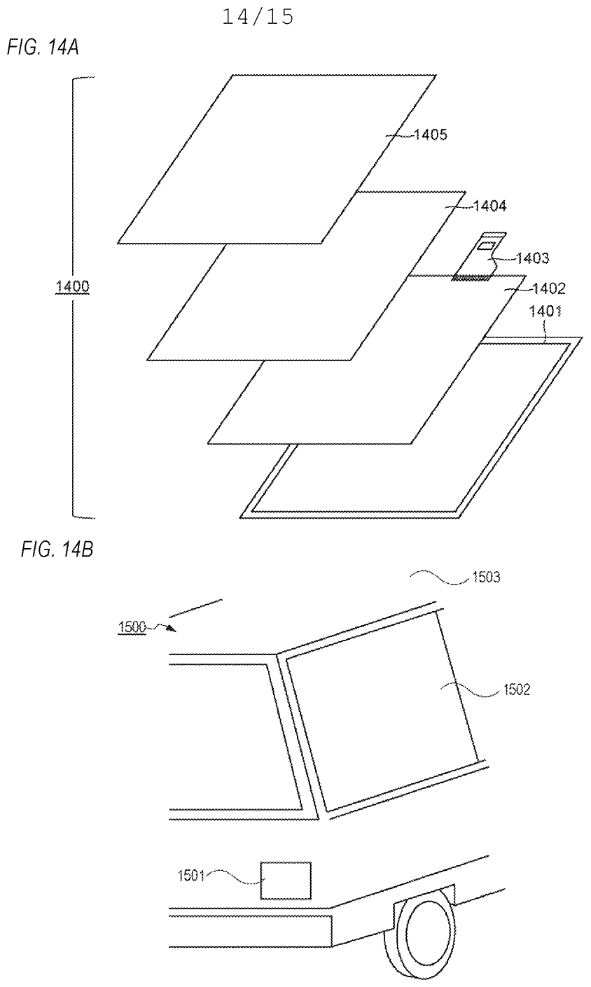

FIG. 14A is a schematic diagram illustrating a lighting device 1400, which is an example of a lighting device according to Embodiment 8. The lighting device 1400 may have a housing 1401, a light source 1402, a circuit board 1403, an optical film 1404, and a light-diffusing part 1405. The light source 1402 has the semiconductor device 800 according to Embodiments 1 to 7. The optical film 1404 may be a filter (optical filter) that improves the color rendering properties of the light source 1402. The light-diffusing part 1405 allows effectively diffusing light from the light source 1402, and allows delivering light over a wide area, for instance in exterior decorative lighting. The optical film 1404 and the light-diffusing part 1405 may be provided on the light exit side of the lighting device 1400. A cover may be provided on the outermost part, as the case may require.

The lighting device 1400 is for instance a device for indoor illumination. The lighting device 1400 may emit white, daylight white, or other colors (any color from blue to red). White denotes herein a color with a color temperature of 4200 K, and daylight white denotes a color with a color temperature of 5000 K. The lighting device 1400 may have a light control circuit for controlling the emission color of the lighting device 1400. The lighting device 1400 may have a power supply circuit connected to the light source 1402. The power supply circuit is a circuit that converts AC voltage to DC voltage. The lighting device 1400 may have a color filter. The lighting device 1400 may have a heat dissipation part. The heat dissipation part dumps, out of the device, heat from inside the device; the heat dissipation part may be made up of a metal or of liquid silicone, exhibiting high specific heat.

FIG. 14B is a schematic diagram illustrating an automobile 1500, which is an example of a moving body according to Embodiment 8. The automobile 1500 may have a tail lamp 1501, which is an example of a lamp. The tail lamp 1501 lights up for instance in response to a braking operation.

The tail lamp 1501 has the semiconductor device 800 according to Embodiments 1 to 7. The tail lamp 1501 may have a protective member that protects semiconductor device 800. The protective member may be made up of any material, so long as the material has a certain degree of high strength and is transparent; the protective member is preferably made up of polycarbonate or the like. For instance a furandicarboxylic acid derivative or an acrylonitrile derivative may be mixed with the polycarbonate.

The automobile 1500 may have a vehicle body 1503 and a window 1502 attached to the vehicle body 1503. The window 1502 may be a transparent display, unless the purpose of the window is to look ahead and behind the automobile 1500. The transparent display may have the semiconductor device 800 according to Embodiments 1 to 7. In that case, constituent materials such as the electrodes of the semiconductor device 800 are made up of transparent members.

The moving body according to Embodiment 8 may be for instance a vessel, an aircraft or a drone. The moving body may have a body frame and a lamp provided on the body frame. The lamp may emit light for indicating the position of the body frame. The lamp includes the semiconductor device 800 according to Embodiments 1 to 7.

The display device according to Embodiment 8 (display device having the semiconductor device 800 according to Embodiments 1 to 7 and that performs display using light emitted from the semiconductor device 800) can be used in a wearable device such as smart glasses, HMDs or smart contacts. The display device according to Embodiment 8 can also be used in a system having a wearable device or the like. An imaging display device used for instance as a wearable device has an imaging device capable of photoelectrically converting visible light, and a display device capable of emitting visible light.

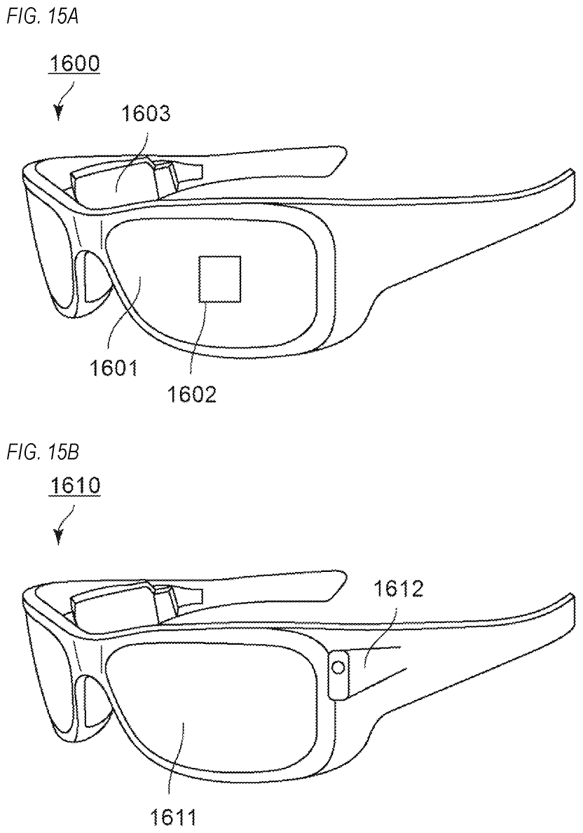

FIG. 15A is a schematic diagram illustrating spectacles 1600 (smart glasses) that are an example of a wearable device according to Embodiment 8. An imaging device 1602 such as a CMOS sensor or a SPAD is provided on the front side of a lens 1601 of the spectacles 1600. On the back surface of the lens 1601 there is provided a display device according to Embodiment 8 (display device having the semiconductor device 800 according to Embodiments 1 to 7 and that performs display using light emitted from the semiconductor device 800).

The spectacles 1600 further include a control device 1603. The control device 1603 functions as a power supply that supplies power to the imaging device 1602 and to the above display device. The control device 1603 controls the operations of the imaging device 1602 and of the display device. The lens 1601 has formed therein an optical system for condensing light onto the imaging device 1602.

FIG. 15B is a schematic diagram illustrating spectacles 1610 (smart glasses) that are an example of the wearable device according to Embodiment 8. The spectacles 1610 have a control device 1612, such that an imaging device corresponding to the imaging device 1602 and a display device according to Embodiment 8 are mounted on the control device 1612. In a lens 1611 there is formed an optical system for projecting light emitted from the imaging device and the display device in the control device 1612 display device, so that an image is projected onto the lens 1611. The control device 1612 functions as a power supply that supplies power to the imaging device and to the display device, and controls the operations of the imaging device and of the display device.

The control device may have a line-of-sight detection unit that detects the line of sight of the wearer of the spectacles 1610. Infrared rays may be used herein for line-of-sight detection. An infrared light-emitting unit emits infrared light towards one eyeball of a user who is gazing at a display image. The emitted infrared light is reflected by the eyeball, and is detected by an imaging unit having a light-receiving element, whereby a captured image of the eyeball is obtained as a result. Impairment of the quality of the image that is projected onto the lens 1611 from the display device is reduced herein by providing a reducing unit for reducing light from the infrared light-emitting unit to the display unit, in a plan view. The control device detects the line of sight of the user with respect to the display image, on the basis of the captured image of the eyeball as obtained through infrared light capture. Any known method can be adopted for line-of-sight detection using the captured image of the eyeball. As an example, a line-of-sight detection method can be resorted to that utilizes Purkinje images obtained through reflection of irradiation light on the cornea. More specifically, line-of-sight detection processing based on a pupillary-corneal reflection method is carried out herein. The line of sight of the user is detected by calculating a line-of-sight vector that represents the orientation (rotation angle) of the eyeball in accordance with a pupillary-corneal reflection method, on the basis of a Purkinje image and a pupil image included in the captured image of the eyeball.

In a case where display control is performed on the basis of visual recognition detection (line-of-sight detection), the semiconductor device 800 according to Embodiments 1 to 7 can be preferably used in smart glasses having an imaging device that captures external images. Smart glasses can display captured external information in real time.

The display device according to Embodiment 8 (display device having the semiconductor device 800 according to Embodiments 1 to 7 and that performs display using light emitted by the semiconductor device 800) may have an imaging device having a light-receiving element, and may control the display image on the basis of information about the line of sight from the imaging device to user. Specifically, a first visual field area gazed at by the user and a second visual field area, other than the first visual field area, are determined on the basis of line-of-sight information. The first visual field area and the second visual field area may be determined by the control device of the display device; alternatively, the display device may receive visual field areas determined by an external control device. In a display area of the display device, display resolution in the first visual field area may be controlled to be higher than the display resolution in the second visual field area. That is, the resolution in the second visual field area may be set to be lower than that of the first visual field area.

The display area may have a first display area and a second display area different from the first display area, and one of the first display area and the second display area may be determined as the area of higher priority on the basis of the line-of-sight information. The first display area and the second display area may be determined by the control device of the display device; alternatively, the display device may receive display areas determined by an external control device. The resolution in a high-priority area may be controlled so as to be higher than the resolution in areas other than high-priority areas. That is, resolution may be reduced in areas of relatively low priority.

Herein AI (Artificial Intelligence) may be used to determine the first visual field area and high-priority areas. The AI may be a model constructed to estimate a line-of-sight angle and the distance to an object lying ahead in the line of sight, from an image of the eyeball, using training data in the form of the image of the eyeball and the direction towards which the eyeball in the image was actually gazing at. An AI program may be provided in the display device, in the imaging device, or in an external device. In a case where an external device has the AI program, the AI program is transmitted to the display device via communication.

As explained above, various devices can stably display images with good image quality, over long periods of time, through the use of the semiconductor device 800 according to Embodiments 1 to 7.

The functional units (configurations) of the various devices explained in Embodiment 8 may or may not be individual pieces of hardware. Functions of two or more functional units may be realized by shared hardware. Each of multiple functions of one functional unit may be implemented by separate pieces of hardware. Two or more functions of one functional unit may be realized by shared hardware. The functional units may or may not be realized by hardware such as ASICs, FPGAs and DSPs. For instance, the device may have a processor and a memory (storage medium) in which a control program is stored. The functions of at least some of the functional units of the device may be realized in that the processor reads out the control program from the memory, and executes the control program.

The present invention succeeds in providing a semiconductor device in which terminals of a semiconductor chip are satisfactorily flip-chip mounted onto the electrodes of a semiconductor substrate.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2023-115249, filed on Jul. 13, 2023, and Japanese Patent Application No. 2024-047666, filed on Mar. 25, 2024, which are hereby incorporated by reference herein in their entirety.

What is claimed is:

1. A semiconductor device comprising:
a semiconductor chip in which a plurality of terminal groups including a plurality of terminals disposed along a first direction are disposed along a second direction that intersects the first direction,
wherein at least one of the plurality of terminal groups includes a first terminal, a second terminal adjacent to the first terminal in the first direction, a third terminal adjacent to the second terminal on an opposite side thereof from the first terminal in the first direction, and a fourth terminal adjacent to the third terminal on an opposite side thereof from the second terminal in the first direction;
a spacing between the first terminal and the second terminal in the first direction is wider than a spacing between the second terminal and the third terminal in the first direction; and
the spacing between the second terminal and the third terminal in the first direction is wider than a spacing between the third terminal and the fourth terminal in the first direction.

2. A semiconductor device comprising:
a semiconductor chip in which a plurality of terminal groups including a plurality of terminals disposed along a first direction are disposed along a second direction that intersects the first direction,
wherein the plurality of terminal groups includes a first terminal group and a second terminal group;
a spacing between a central portion of the first terminal group in the first direction and a central portion of the second terminal group in the first direction is narrower than a spacing between an intermediate portion disposed between the central portion and an end portion of the first terminal group in the first direction, and an intermediate portion disposed between the central portion and an end portion of the second terminal group in the first direction; and
a spacing between the intermediate portion of the first terminal group in the first direction and the intermediate portion of the second terminal group in the first direction is narrower than a spacing between the end portion of the first terminal group in the first direction and the end portion of the second terminal group in the first direction.

3. The semiconductor device according to claim 2,
wherein a position of the terminal in the second direction differ between the central portion of the first terminal group and the end portion of the first terminal group.

4. The semiconductor device according to claim 3,
wherein a position of the terminal in the second direction differs between the central portion of the second terminal group and the end portion of the second terminal group.

5. The semiconductor device according to claim 2,
wherein a size of the terminal in the second direction at the central portion of the first terminal group is larger than a size of the terminal in the second direction at the end portion of the first terminal group.

6. The semiconductor device according to claim 5,
wherein a size of the terminal in the second direction at the central portion of the second terminal group is larger than a size of the terminal in the second direction at the end portion of the second terminal group.

7. The semiconductor device according to claim 2,
wherein a spacing between the first terminal group and the second terminal group narrows down gradually with increasing proximity to a center of the first terminal group in the first direction.

8. The semiconductor device according to claim 2,
wherein one of the first terminal group and the second terminal group is an input terminal group, and
the other of the first terminal group and the second terminal group is an output terminal group.

9. The semiconductor device according to claim 2, wherein
at least one of the plurality of terminal groups includes a first terminal, a second terminal adjacent to the first terminal in the first direction, and a third terminal adjacent to the second terminal on an opposite side thereof from the first terminal in the first direction, and
a spacing between the first terminal and the second terminal in the first direction is wider than a spacing between the second terminal and the third terminal in the first direction.

10. The semiconductor device according to claim 1,
wherein in at least one of the plurality of terminal groups, a spacing between two terminals adjacent to each other in the first direction widens gradually with increasing proximity to the center of the terminal group in the first direction.

11. The semiconductor device according to claim 1,
wherein the first direction is a row direction and the second direction is a column direction.

12. The semiconductor device according to claim 1, further comprising
a semiconductor substrate provided with a plurality of electrodes connected respectively, via a connection member, to the plurality of terminals of the semiconductor chip.

13. The semiconductor device according to claim 12,
wherein the plurality of terminals of the semiconductor chip and the plurality of electrodes of the semiconductor substrate are connected to each other by thermocompression bonding or ultrasonic compression joining using an epoxy resin, an acrylic resin or an anisotropic conductive resin as the connection member.

14. A display device comprising:
a display unit having the semiconductor device according to claim 1; and
a control circuit configured to control the display unit.

15. A photoelectric conversion device comprising:
an optical unit;
an imaging element configured to receive light that has passed through the optical unit; and
a display unit configured to display an image captured by the imaging element,
wherein the display unit has the semiconductor device according to claim 1.

16. An electronic device comprising:
a display unit having the semiconductor device according to claim 1;
a housing in which the display unit is provided; and
a communication unit that is provided in the housing and that communicates with the exterior.
